(19) United States
(12) Patent Application Publication
(10) Pub. No.: US 2025/0197192 A1
(43) Pub. Date: Jun. 19, 2025

(54) ANTI-STICTION PATTERNING WITHIN MEMS LAYER

(71) Applicant: InvenSense, Inc., San Jose, CA (US)

(72) Inventors: Sarah Nitzan, Palo Alto, CA (US); Matthew Julian Thompson, Beaverton, OR (US); Mostafa Baghdadi, Monza (IT)

(21) Appl. No.: 18/980,803

(22) Filed: Dec. 13, 2024

Related U.S. Application Data
(60) Provisional application No. 63/610,557, filed on Dec. 15, 2023.

(51) Int. Cl. B81B 3/00; B81C 1/00

(52) U.S. Cl. CPC B81B 3/001; B81C 1/00968; B81B 2201/0235; B81B 2201/0242; B81B 2201/0257; B81B 2201/0264; B81B 2203/0127

(57) ABSTRACT

A proof mass of a MEMS sensor is located above one or more bump stops that extend in the direction of the proof mass from a base substrate, and that are intended to prevent high-impact collisions between the proof mass and base substrate such as when the sensor is dropped or experiences other substantial external forces. A portion of the proof mass located above the bump stop is patterned at the same time that the functional features of the MEMS layer such as springs and masses are fabricated. The patterning reduces stiction between the proof mass and the bump stop, allowing the MEMS sensor to resume operation promptly after an event that results in contact between the proof mass and the bump stop.

### CROSS-REFERENCE TO RELATED APPLICATION

The present application claims priority to U.S. Provisional Patent Application No. 63/610,557, filed Dec. 15, 2023, and entitled “Bumpstop Patterning To Reduce Stiction,” which is herein incorporated by reference in its entirety.

### BACKGROUND

Numerous items such as smart phones, smart watches, tablets, automobiles, aerial drones, appliances, aircraft, exercise aids, and game controllers may utilize sensors such as microelectromechanical system (MEMS) sensors during their operation. In many applications, various types of motion sensors such as accelerometers and gyroscopes may be analyzed independently or together in order to determine varied information for particular applications. For example, gyroscopes and accelerometers may be used in gaming applications (e.g., smart phones or game controllers) to capture complex movements by a user, drones and other aircraft may determine orientation based on gyroscope measurements (e.g., roll, pitch, and yaw), and vehicles may utilize measurements for determining direction (e.g., for dead reckoning) and safety (e.g., to recognizing skid or roll-over conditions).

A MEMS sensor such as a MEMS accelerometer includes a proof mass that moves in response to a force of interest such as linear acceleration in a particular direction. The movement of the proof mass in response to the linear acceleration is measured such as by sense electrodes that are located at a fixed position relative to the proof mass. The MEMS accelerometer may include bump stops that prevent excessive movements of the proof mass such as due to dropping or other shocks, that could otherwise cause damage to the proof mass, sense electrodes, or other electrical or mechanical components of the MEMS accelerometer. In some instances, due to “stiction” forces the proof mass may become stuck to the bump stop such that it does not release from the bump stop even in response to a linear acceleration in the sense direction. Reducing the contact area by reducing bumpstop area can reduce the stiction force, but such bumpstops could be prone to chipping or damage.

### SUMMARY

In an embodiment of the present disclosure, a MEMS sensor comprises a base substrate layer, a MEMS layer comprising a proof mass that moves in a direction towards the base substrate layer and that has a first surface that faces the base substrate layer, and a bump stop located on the base substrate layer and below an overlapping portion of the first surface of the proof mass. In some embodiments, a first pattern is created by a removal of a first portion of material from the proof mass that is located within the overlapping portion of the first surface, and resulting in a reduced contacting area between the proof mass and the bump stop in response to an external force causing the proof mass to contact the bump stop. In some embodiments, a second portion of the material within the MEMS layer is removed at additional locations remote from the overlapping portion, wherein the removal of the second portion of material corresponds to functional components of a suspended spring-mass system. In some embodiments, the first portion of material and the second portion of the material are removed from the MEMS layer during common material removal steps, and the first pattern extends only partially into the MEMS layer.

In an embodiment of the present disclosure, a method for fabricating a MEMS sensor comprises providing a MEMS layer and patterning the MEMS layer, wherein a first portion of the patterning comprises a first pattern corresponding a first portion of the MEMS layer that overlaps with a bump stop located below the MEMS layer and results in a reduced surface area that comes into contact with the bump stop in response to an external force causing a proof mass to contact the bump stop. In some embodiments, a second portion of the patterning comprises a second pattern corresponding to a second portion of the MEMS layer that is remote from the first portion of the MEMS layer and that corresponds to functional components of a suspended spring-mass system. The method can further include simultaneously partially removing material from the MEMS layer based on the first pattern and completely removing material from the MEMS layer based on the second pattern to fabricate the first pattern that overlaps with the bump stop and the second pattern that corresponds to functional components of the suspended spring-mass system.

providing a MEMS layer, applying a mask over the MEMS layer, and patterning the mask, wherein a first portion of the patterning comprises a first pattern corresponding a first portion of the MEMS layer that overlaps with a bump stop located below the MEMS layer and results in a reduced surface area that comes into contact with the bump stop in response to an external force causing a proof mass to contact the bump stop, and wherein a second portion of the patterning comprises a second pattern corresponding to a second portion of the MEMS layer that is remote from the first portion of the MEMS layer and that corresponds to functional components of a suspended spring-mass system. The method further comprises simultaneously removing material from the MEMS layer based on the first pattern and the second pattern to fabricate the first pattern that overlaps with the bump stop and the second pattern that corresponds to functional components of a suspended spring-mass system.

### BRIEF DESCRIPTION OF DRAWINGS

The above and other features of the present disclosure, its nature, and various advantages will be more apparent upon consideration of the following detailed description, taken in conjunction with the accompanying drawings in which:

FIG. 1 shows an illustrative MEMS system in accordance with an embodiment of the present disclosure;

FIG. 2A depicts a top view of a MEMS device containing a proof mass in accordance with an embodiment of the present disclosure;

FIG. 2B depicts a side view of a MEMS device along a section line containing a proof mass in accordance with an embodiment of the present disclosure;

FIG. 2C depicts a side view of a MEMS device along a section line containing a proof mass that is stuck to a bump stop in accordance with an embodiment of the present disclosure;

FIG. 3A depicts a top view of a MEMS device containing a proof mass with anti-stiction patterning in accordance with an embodiment of the present disclosure;

FIG. 3B depicts a side view of a MEMS device along a section line containing a proof mass with anti-stiction patterning in accordance with an embodiment of the present disclosure;

FIG. 3C depicts a side view of a MEMS device along a section line containing a proof mass with anti-stiction patterning that is in contact with a bump stop in accordance with an embodiment of the present disclosure;

FIG. 4A depicts a top view of an anti-stiction patterned portion of a proof mass comprised of through-hole elements in accordance with an embodiment of the present disclosure;

FIG. 4B depicts a side view of an anti-stiction patterned proof mass comprised of through-hole elements along a section line in accordance with an embodiment of the present disclosure;

FIG. 4C depicts a top view of a bump stop with an above projection of an anti-stiction patterned portion of proof mass comprised of through-hole elements in accordance with an embodiment of the present disclosure;

FIG. 5A depicts a top view of an anti-stiction patterned portion of a proof mass comprised of diagonal slit elements in accordance with an embodiment of the present disclosure;

FIG. 5B depicts a side view of an anti-stiction patterned proof mass comprised of diagonal slit elements along a section line in accordance with an embodiment of the present disclosure;

FIG. 6A depicts a top view of an anti-stiction patterned portion of a proof mass comprised of partial through-hole elements in accordance with an embodiment of the present disclosure;

FIG. 6B depicts a side view of an anti-stiction patterned proof mass comprised of partial through-hole elements along a section line in accordance with an embodiment of the present disclosure;

FIG. 7A depicts a top view of an anti-stiction patterned portion of a proof mass comprised of pillar elements in accordance with an embodiment of the present disclosure;

FIG. 7B depicts a side view of an anti-stiction patterned proof mass comprised of pillar elements along a section line in accordance with an embodiment of the present disclosure;

FIG. 8 depicts a side view of a MEMS layer during the fabrication process for through-hole anti-stiction patterning of a MEMS layer in accordance with an embodiment of the present disclosure;

FIG. 9 depicts a side view of a MEMS layer during the fabrication process for partial through-hole anti-stiction patterning of a MEMS layer in accordance with an embodiment of the present disclosure;

FIG. 10 depicts a flow diagram for a method of anti-stiction patterning of a MEMS layer according to one aspect of an embodiment within the present disclosure.

### DETAILED DESCRIPTION

A MEMS sensor such as a MEMS accelerometer includes movable components such as a proof mass that move in accordance with the manner in which they are suspended within the MEMS layer (e.g., based on position and configuration of springs, masses, lever arms, etc.) and forces exerted on the proof mass. Under normal operation, the proof mass has a range of motion in response to expected forces and that motion is measured such as by fixed sense electrodes that form capacitive sensors with the moving proof mass. However, when an extreme force such as when a device is dropped or engaged in a collision occurs, the proof mass may move well beyond that expected range of motion and with high force, potentially resulting in damage due to collision (such as to the proof mass or sense electrodes) or due to over-deflection of features such as springs, resulting in breakage. Accordingly, bump stops are placed between a proof mass and adjacent components or layers to limit the range of motion during such events and to absorb the impact of the force of the proof mass. Although the bump stops may perform this protective function, the surface of the proof mass may become stuck to the bump stop such as by stiction (e.g., adhesion) forces, such that the restorative force of springs within the MEMS layer is inadequate to return the proof mass to its normal position.

The surfaces of the proof mass that come into contact with the bump stops may be patterned in a manner that reduces the stiction (e.g., adhesion) force when the proof mass contacts the bump stop. The patterning may be performed to create a variety of shapes and profiles, such as “holes” in the surface that contacts the bump stop, “strips” in the surface that contacts the bump stop, or “pillars” that extend down to and contact the bump stop. Other types of patterns including other shapes and constructs may be utilized, and multiple patterns may be combined. The patterning at the surface of the proof mass that contacts the bump stop substantially reduces the adhesion force with the bump stop, such that the original position of the proof mass is restored by the force of springs suspending the proof mass and/or other techniques (e.g., electrodes to move the proof mass). During fabrication, the patterning of the anti-stiction features may be performed simultaneously with the patterning of the functional features of the proof mass such as springs, proof masses, and the like. Accordingly, the anti-stiction features may be created with minimal additional material or fabrication cost.

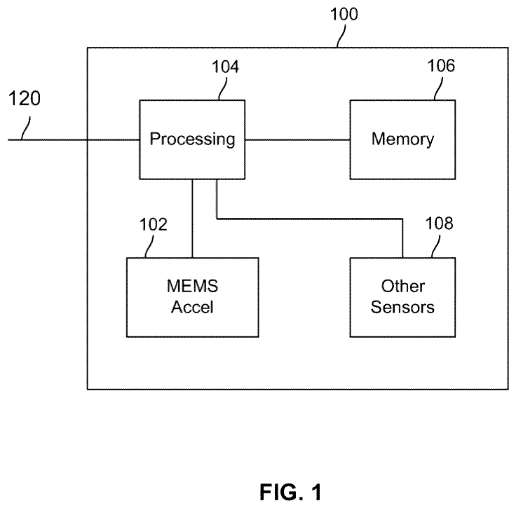

FIG. 1 shows an illustrative MEMS system 100 in accordance with an embodiment of the present disclosure. Although particular components are depicted in FIG. 1, it will be understood that other suitable combinations of the MEMS, processing components, memory, and other circuitry may be utilized as necessary for different applications and systems. In accordance with the present disclosure, the MEMS system may include a MEMS accelerometer 102 as well as additional sensors 108. Although the present disclosure will be described in the context of signals received from MEMS accelerometers, it will be understood that the patterning of the of the present disclosure may be utilized with any proof mass or other movable component that may come in contact with a bump stop or other similar fixed components.

Processing circuitry 104 may include one or more components providing processing based on the requirements of the MEMS system 100. In some embodiments, processing circuitry 104 may include hardware control logic that may be integrated within a chip of a sensor (e.g., on a base substrate of a MEMS accelerometer 102 or other sensors 108, or on an adjacent portion of a chip to the MEMS accelerometer 102 or other sensors 108) to control the operation of the MEMS accelerometer 102 or other sensors 108 and perform aspects of processing for the MEMS accelerometer 102 or the other sensors 108. In some embodiments, the MEMS accelerometer 102 and other sensors 108 may include one or more registers that allow aspects of the operation of hardware control logic to be modified (e.g., by modifying a value of a register). In some embodiments, processing circuitry 104 may also include a processor such as a microprocessor that executes software instructions, e.g., that are stored in memory 106. The microprocessor may control the operation of the MEMS accelerometer 102 by interacting with the hardware control logic and processing signals received from MEMS accelerometer 102. The microprocessor may interact with other sensors 108 in a similar manner. In some embodiments, some or all of the functions of the processing circuitry 104, and in some embodiments, of memory 106, may be implemented on an application specific integrated circuit (“ASIC”) and/or a field programmable gate array (“FPGA”).

Although in some embodiments (not depicted in FIG. 1), the MEMS accelerometer 102 or other sensors 108 may communicate directly with external circuitry (e.g., via a serial bus or direct connection to sensor outputs and control inputs), in an embodiment the processing circuitry 104 may process data received from the MEMS accelerometer 102 and other sensors 108 and communicate with external components via a communication interface 110 (e.g., a serial peripheral interface (SPI) or I2C bus, in automotive applications a controller area network (CAN) or Local Interconnect Network (LIN) bus, or in other applications a suitably wired or wireless communications interface as is known in the art). The processing circuitry 104 may convert signals received from the MEMS accelerometer 102 and other sensors 108 into appropriate measurement units (e.g., based on settings provided by other computing units communicating over the communication interface 110) and perform more complex processing to determine measurements such as orientation or Euler angles, and in some embodiments, to determine from sensor data whether a particular activity (e.g., walking, running, braking, skidding, rolling, etc.) is taking place. In some embodiments, some or all of the conversions or calculations may take place on the hardware control logic or other on-chip processing of the MEMS accelerometer 102 or other sensors 108.

In some embodiments, certain types of information may be determined based on data from multiple MEMS accelerometers 102 and other sensors 108 in a process that may be referred to as sensor fusion. By combining information from a variety of sensors it may be possible to accurately determine information that is useful in a variety of applications, such as image stabilization, navigation systems, automotive controls and safety, dead reckoning, remote control and gaming devices, activity sensors, 3-dimensional cameras, industrial automation, and numerous other applications.

In embodiments of the present disclosure, a movable component such as a proof mass within a MEMS layer of a MEMS device such as a MEMS accelerometer 102 may be patterned such that material is removed from the proof mass (e.g., partial removal into the MEMS layer and/or complete removal through the MEMS layer) at a surface of the proof mass that is facing a fixed component such as a bump stop. When the proof mass comes into contact with the bump stop, a substantial portion of the proof mass has material removed and thus there is a corresponding reduction in the potential stiction (e.g., adhesion) force between the proof mass and bump stop. Further, because there is no continuity of stiction at the proof mass/bump stop interface, any resulting stiction force may be more easily overcome. In some implementations, this may allow for larger bump stop designs and/or no need for anti-stiction layers or coatings over sensor component layers.

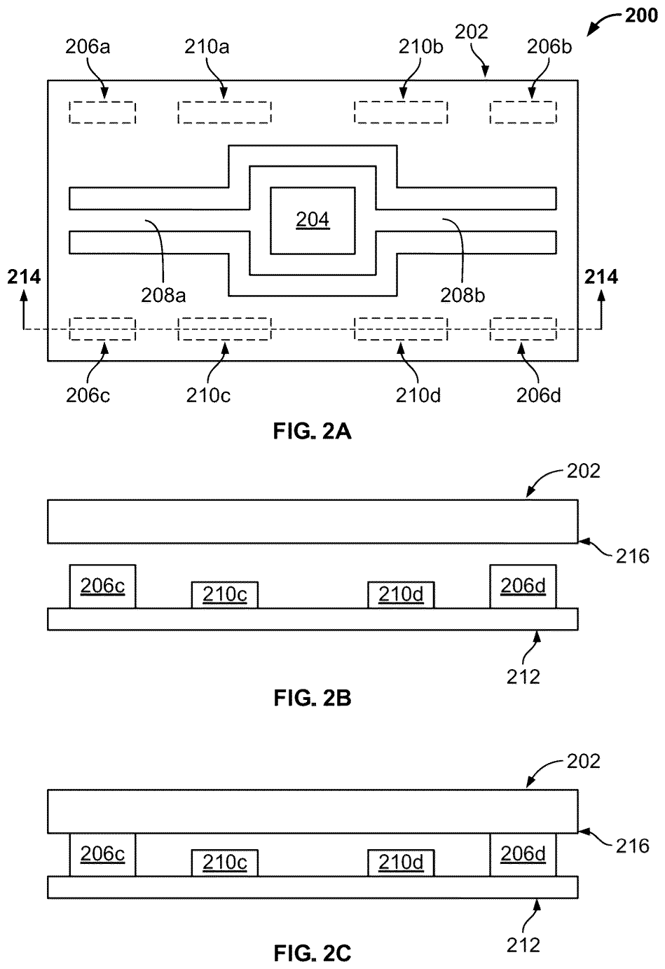

FIG. 2A depicts a top view of a MEMS device having a proof mass, in accordance with an embodiment of the present disclosure. It is understood that a MEMS device 200 may have a number of different configurations and components. In an exemplary embodiment, the MEMS device 200 includes a proof mass 202 that is supported by an anchor 204. To prevent the proof mass 202 from colliding with the substrate 212 or other components, one or more bump stops 206 are located in a lower parallel plane on a base substrate (not depicted). Sense springs 208 rotate torsionally about their long axis in response to a force of interest, and the build up of torsional force within the sense springs 208 assists in returning the proof mass 202 back to its resting state after an external force is applied and when the proof mass comes into contact with bump stops 206. Sense electrodes 210 give feedback (e.g., capacitance measurements) on the movements of the proof mass 202 and may indicate if the proof mass 202 is stuck to the bump stops 206 (e.g., is not moving such that capacitance does not change), as may occur during normal device functioning as described further below.

FIG. 2B depicts a side view of a MEMS device along a section line 214 aligned with the proof mass, while FIG. 2C depicts the same side view of the MEMS device along the section line 214 where the proof mass is in contact with a bump stop in accordance with an embodiment of the present disclosure. Note that the side of the proof mass 202 opposite the sense springs 208 is rotated upwards in the event of a collision between the proof mass 202 and bump stops 206. This rotation is not depicted in FIG. 2C, or any of the other similar depictions shown later on, for case of viewing. If an extreme external force is applied to the device, it may elicit a strong collision between the first surface 216 of a proof mass 202 and the bump stops 206. The generated stiction (e.g., adhesion) forces may prevent the proof mass 202 from detaching from the bump stops 206 and returning to its resting position (as demonstrated in FIG. 2C).

Proof mass 202 may be a moveable component within a MEMS device 200. While only one proof mass 202 is depicted within FIG. 2, any number of proof masses 202 may be included within a single MEMS device 200 (e.g., one for each spatial axis), each with their own unique geometry, design, support structures, thickness, and configuration. Generally, the proof mass 202 is configured to move in response to an external force to the MEMS device 200. The direction of movement (x, y, or z-axis) is dependent on the configuration of the MEMS device 200, the direction of the applied force, and how the proof mass 202 is positioned within the MEMS layer. In cases where the external force is large, an extreme movement of the proof mass 202 may occur that risks collision of its first surface 216 with other components. Therefore, bump stops 206 may be present within the MEMS accelerometer 200 whose purpose is to limit the deflection of the proof mass 202, thereby reducing the possibility of damage to the proof mass 202 and/or other components of the MEMS device 200. One or more sense springs 208 may suspend the proof mass 202 in its own spatial plane and may provide a restoring force to return proof mass 202 back to its resting position once the acceleration or applied external force has diminished. In some embodiments the proof mass 202 may also be supported by one or more anchors 204. A change in position (i.e., the amount of movement) of the proof mass 202 within the MEMS accelerometer 200 may be determined using one or more sense electrodes 210 that are capable of measuring changes in a particular value (e.g., capacitance, inductance, resistance) that varies in response to positional changes of the proof mass 202.

Contact between the proof mass 202 and other components of MEMS device 200 may occur along a first surface 216 of the proof mass 202. The first surface 216 may be a lower or lowermost surface of the proof mass 202. During the fabrication process (e.g., etching stage) of the MEMS device 200, the first surface 216 of the proof mass 202 may be etched in such a way (will be discussed later on) that the surface exhibits particular desired characteristics. For example, as will be discussed further below, the planarity, roughness, material, thickness, curvature, elasticity, and patterning of the first surface 216 may be modified to induce particular changes to the function and behavior of the proof mass 202 where it contacts bump stops 206, and thus the performance of MEMS device 200 as a whole.

The anchor 204 is a fixed, immovable structure on the substrate 212 that acts as an attachment point for the proof mass 202 (or other device components), thus allowing the proof mass 202 to have controlled and predictable movements once an external force is applied to the system. The anchor 204 also serves to provide rigidity and structural integrity to the entire MEMS device 200. Similar to the proof mass 202, it may be fabricated from a variety materials (e.g., silicon, polysilicon). While only one anchor 204 is depicted within FIG. 2A, any number of anchors 204 may be included within a single MEMS device 200, each with their own unique geometry (e.g., plate, beam), design, material, thickness, and configuration.

One or more bump stops 206 may be positioned on the substrate 212. Generally, bump stops 206 ensure that the proof mass 202 doesn't move from a nominal position beyond a point where damage or breakage would occur, e.g., by contacting other components of the MEMS device 200. Additionally, bump stops 206 may protect other MEMS components within the device from collisions caused by extreme external forces. While the bump stops 206 may generally be made from the same material as other components of the MEMS device 200, the material(s) may contain additives to make them relatively more elastic, and thus better able to absorb sudden bursts of kinetic energy. Similar to the etching that may be done on the proof mass 202, bump stops 206 may also be fabricated with topographical patterns on one or more surfaces of the bump stops 206.

After a collision between the proof mass 202 and bump stop 206, a stiction force may delay or may fully prevent the proof mass 202 from returning to its resting position. In some embodiments there may be multiple bump stops 206 in various locations across the MEMS device 200. For example, as best seen in FIG. 2A, a first tail bump stop 206c and a second tail bump stop 206d may be positioned in a parallel plane towards the lower corners of the proof mass 202, and a first head bump stop 206a and second head bump stop 206b may be positioned in a parallel plane towards the upper corners of the proof mass 202. Such a configuration allows for greater protection of the proof mass 202 compared with embodiments having fewer bump stops 206. In some cases, greater numbers of bump stops 206 may distribute external force across a larger surface area (i.e., several bump stops), thus reducing the kinetic energy each bump stop 206 would have to absorb in comparison to an example with a single bump stop 206. While the illustrated example has bump stops 206 of similar size, in other examples a size, location, design, and/or shape of the bump stops 206 varies within a single MEMS device 200.

MEMS devices 200 may contain sense springs 208 that suspend the proof mass 202 from the substrate 212 and allow it to move in relative to the substrate 212 in response to external forces. The geometry, number, thickness, and general configuration of the sense springs 208 may vary across MEMS devices 200 depending on a multitude of considerations (e.g., direction of movement of the proof mass 202). Each sense spring 208 has a respective spring constant that determines in part a strength of its restoring force, a sensitivity, and an operational range of the MEMS device 200. Stiffer springs can better withstand larger external forces and are implemented in devices that require wide measurement ranges. Conversely, more flexible springs allow for greater displacement of the proof mass 202, thus increasing the sensitivity of the device. After an external force causes the proof mass 202 to move in one direction, the restoring force of the sense spring 208 pulls the proof mass 202 in the opposite direction. If a strong stiction force exists (e.g., between the proof mass 202 and bump stop 206), then a restoring force of the sense springs 208 may not be able to return the proof mass 202 to its resting position. In that case, the MEMS device 200 may be unable to properly function until the proof mass 202 is restored to its original state.

Sense electrodes 210 are present within MEMS devices 200 in order to give feedback (e.g., capacitance measurements) on the movements of the proof mass 202 within the device. The geometry, number, location, material, coating, and general configuration of the sense electrodes 210 may vary across MEMS devices 200. In most embodiments, the amount of their projection/protrusion from the surface of the substrate 212 is always less than that of the bump stops 206 (to reduce the possibility of contact between the sense electrode(s) 210 and the proof mass 202, thereby ensuring physical protection of the sense electrode(s) 210). For example, the sense electrodes 210 may be one component of a parallel-plate capacitor system, where another is the proof mass 202. External forces acting on the MEMS device 200 may cause a movement in the proof mass 202, thus leading to a transient change in the measured capacitance within the parallel-plate capacitator system due to the change in distance between the parallel-plates. With the aid of the sense electrodes 210, it is possible to determine if the proof mass 202 becomes stuck to a bump stop 206 after an external force is applied the MEMS device 200, e.g., as demonstrated in FIG. 2C where there is direct contact between the first surface 216 of the proof mass 202 and the bump stops 206. Under normal working conditions, the restoring force provided by the sense springs 206 is able to overcome typical stiction forces that may be encountered during the movement of the proof mass 202. The capacitance levels are transiently altered during the movement of the proof mass 202 and return to steady-state values when the proof mass 202 is returned to its original position. In those cases, the proof mass 202 is not stuck to the bump stops 206 and normal functioning of the MEMS device 200 continues. However, after an external force is applied to the MEMS device 200 (e.g., in some instances, a force that causes contact with a bump stop but does not create a “bounce” that can release the bumpstop, or in other instances a large or extreme force), a collision between the proof mass 200 and bump stops 206 may generate stiction forces greater than the restoring force provided by the sense springs 208, thus preventing the return of the proof mass 202 to its resting position and the capacitance back to the original steady-state values. The measurement of this persistent change in capacitance levels indicates the proof mass 202 is stuck to the bump stops 206. Circuitry (e.g., microcontrollers, electrical connections) for the sense electrodes 210 may be located on or within the substrate 212 and may be driven with either an AC or DC power supply.

The base substrate 212 serves to physically support not only other MEMS components (e.g., electrodes, sensors, microcontrollers), but also to act as an interface for electrical and/or mechanical connections (e.g., including processing circuitry such as CMOS circuitry and an ASIC). The geometry, thickness, and general configuration of the substrate 212 may vary across MEMS devices 200. Note that the exterior dimensions of the MEMS device 200 are generally set by the dimensions of the substrate 212.

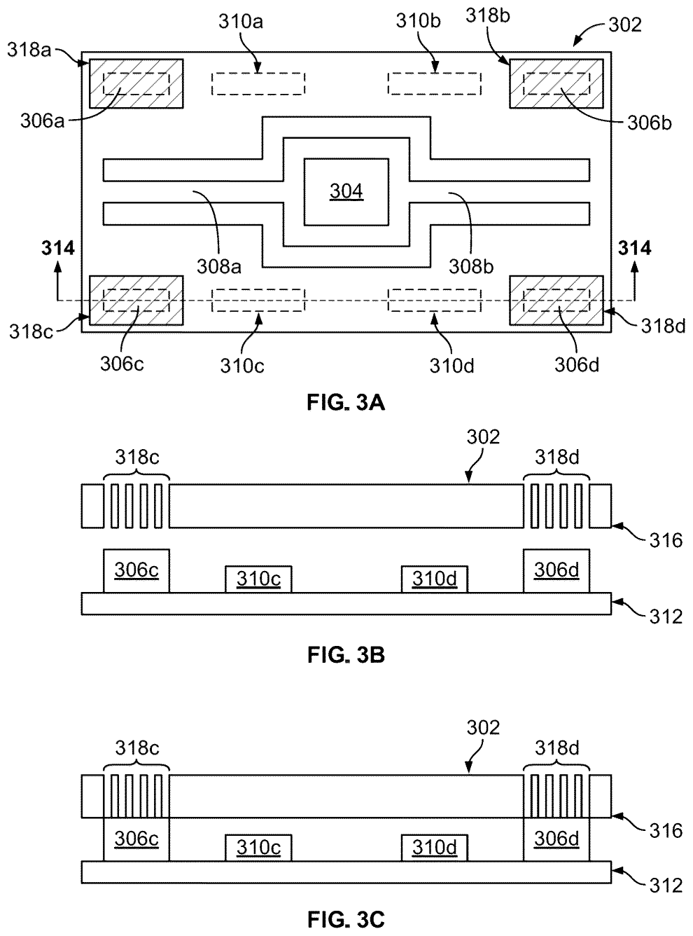

FIG. 3A depicts a top view of a MEMS device containing a proof mass with anti-stiction patterning in accordance with an embodiment of the present disclosure. This MEMS device 300 is similar to and functions in a similar manner as that of the MEMS device 200. However, the proof mass exhibits anti-stiction patterning 318a-318d, referred to as 318 in areas on the first surface 316 that would tend to contact the bump stops 306 (i.e., directly above the bump stops 306). The anti-stiction patterning 318 may be formed by removing certain portions of the first surface 316 of the proof mass 302. FIG. 3B depicts a side view of the MEMS device 300 along a section line 314. When an extreme external force is applied to MEMS device 300, a collision may occur between the bump stops 306 and the first surface 316 of the proof mass 302. The generated stiction forces may be reduced due to the presence of the anti-stiction patterning 318 on the first surface 316 of the proof mass 302. When the proof mass 302 comes in contact with the bump stops 306, as depicted in FIG. 3C, the reduced amount of surface area contact afforded by the anti-stiction patterning 318 may allow for the restoring force of the sense springs 308 to return the proof mass 302 back to its resting position, thus ensuring proper functionality of the MEMS device 300.

The numbered elements of FIGS. 3A-3C are similar to and function in a similar manner as the components of FIG. 2A-2C. However, the first surface 316 of the proof mass 302 has been altered during the fabrication process to pattern particular portions of it. One method of reducing stiction forces within MEMS systems is reducing an amount of contact surface area between the proof mass 302 and the bump stops 306. In an example, removing some of the first surface 316 of the proof mass 302 during the fabrication process reduces the contact area between the proof mass 302 and the bump stops 306 in the event of a collision. The size, location, shape, design, curvature, linearity, surface area of overlapping portion, proximity to functional components, amount of removed volume, and pattern density of the elements within the anti-stiction pattern 318 may be configured during the fabrication process (as will be discussed further below). In some embodiments the pattern may be a through-hole design where holes are etched fully through a thickness of the proof mass 302. In at least some embodiments partial holes are utilized (i.e., holes etched partially through a thickness of the proof mass 302). Alternatively, pillars may be constructed by removing material of the proof mass 302 to create patches of topographical disparity. By altering a density of the anti-stiction pattern 318 (i.e., a number of through-holes, partial holes, pillars, etc. within a given area), a contact area between the proof mass 302 and bump stop 306 in the event of a collision may be controlled. An amount of overlap between the anti-stiction pattern 318 on the proof mass 302 and the bump stop 306 may be configured during a fabrication process. Particular processing tolerances exist in the fabrication process of MEMS devices 300 that leads to irregularities and non-idealities. As such, it may be beneficial in some cases to extend an overlap of the anti-stiction pattern 318 with the bump stop 306, whereby an excess of anti-stiction pattern 318 is etched (i.e., as an overhang from the bump stop 306). In some embodiments, the anti-stiction pattern 318 may be linear and evenly-spaced across a specific portion of the proof mass 302, while in other embodiments the pattern may be irregular and offset, such that no linear dimension of the bump stop 306 may come in contact with the overlapping portion of the proof mass 302 in the event of a collision.

Although FIG. 3 is depicted as a proof mass, such as of an inertial sensor, it is understood that the present disclosure may be utilized in a variety of MEMS devices where a moving structure may come into contact with another surface, thus creating stiction (e.g., a diaphragm of a MEMS pressure sensor or MEMS microphone).

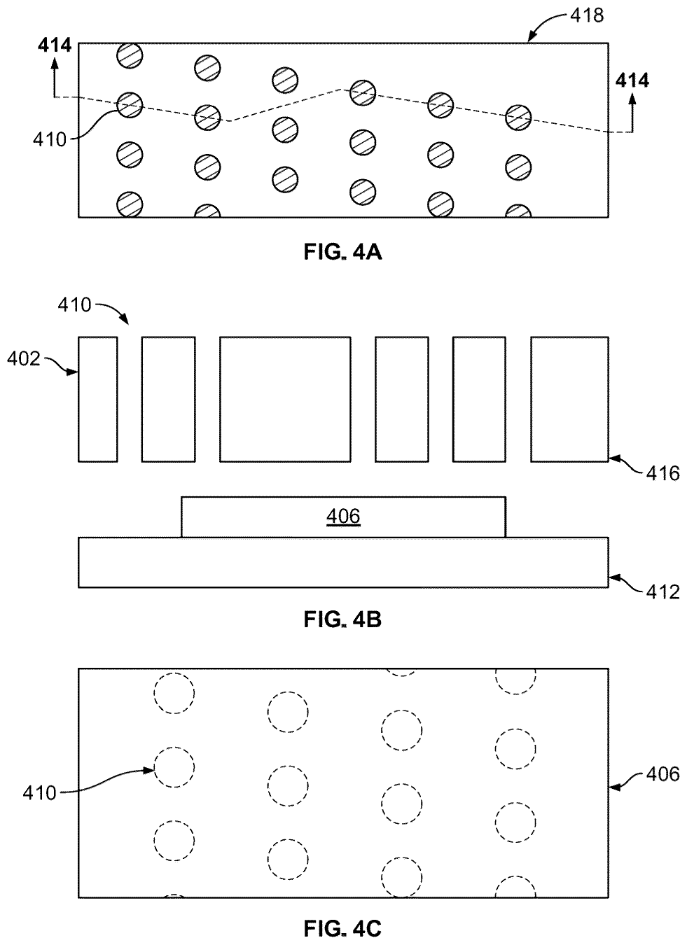

FIG. 4A depicts a top view of an anti-stiction patterned portion of a proof mass comprised of through-hole elements in accordance with an embodiment of the present disclosure. This MEMS device 400 is similar to and functions in a similar manner as that of the MEMS device 300. The anti-stiction pattern 418 is comprised of through-hole elements 410 offset from one another in a diagonal line. FIG. 4B depicts a side view of the MEMS device 400 along a section line 414. The anti-stiction pattern 418 may be applied along an extent that is greater than the width of the bump stop 406 to account for any irregularities and non-idealities in the fabrication process of the MEMS device 400. For example, to an extent that the bump stop 406 is formed with a larger width than intended, additional through-hole elements 410 may be formed in the proof mass 402. As depicted in FIG. 4C, which shows a projection of the through-hole elements 410 onto the upper surface of the bump stop 406, the anti-stiction patterning present on the first surface 416 of the proof mass 402 ensures that the number of continuous surface contacts between the proof mass 402 and bump stop 406 is relatively low compared with a non-patterned or continuous bump stop.

The numbered elements of FIGS. 4A-4C are similar to and function in a similar manner as the components of FIGS. 3A-3C. However, a more detailed view on the specific overlap of an anti-stiction pattern 418 comprised of through-hole elements 410 with a single bump stop 406 is shown. The through-hole elements 410 are etched diagonally into the first surface 416 of the proof mass 402, which ensures that in the event of a collision, no continuous linear dimension of the bump stop 406 may come in contact with the first surface 416 of the proof mass 402. While a diagonal pattern is shown in this embodiment, others may utilize patterns of varying degrees of offset, spacing, and linearity to achieve a particular performance of the MEMS device 400. Some embodiments may even employ anti-stiction patterns 418 with varying designs of elements across an individual bump stop 406 or between bump stops 406 within the MEMS device 400.

A through-hole element 410 is utilized within the anti-stiction pattern 418 that is etched on the first surface 416 such that the through-hole 410 extends fully through the proof mass 402, such that the through-hole element 410 is present in a top and a bottom surface of the proof mass 402 and as such is displayed in the pattern. A size/diameter, location, shape, design, curvature, linearity, proximity to functional components, amount of removed volume, and pattern density of the though-hole elements 410 may be configured during the fabrication process (will be discussed later on). In cases where an extreme external force is applied to the MEMS device 400, the proof mass 402 may collide with the bump stops 406 generating stiction forces. Through the use of the through-hole elements 410, the amount of contact area between the first surface 416 of the proof mass 402 and the bump stop 406 may be reduced compared with proof masses formed without through-holes or other patterns in surfaces of the proof mass 402. In at least some examples, stiction forces are influenced directly by an amount of surface area in contact between the elements in contact, and as such the reduced amount of contact area possible in the example illustrated in FIGS. 4A-4C generally diminishes a strength of the generated stiction forces.

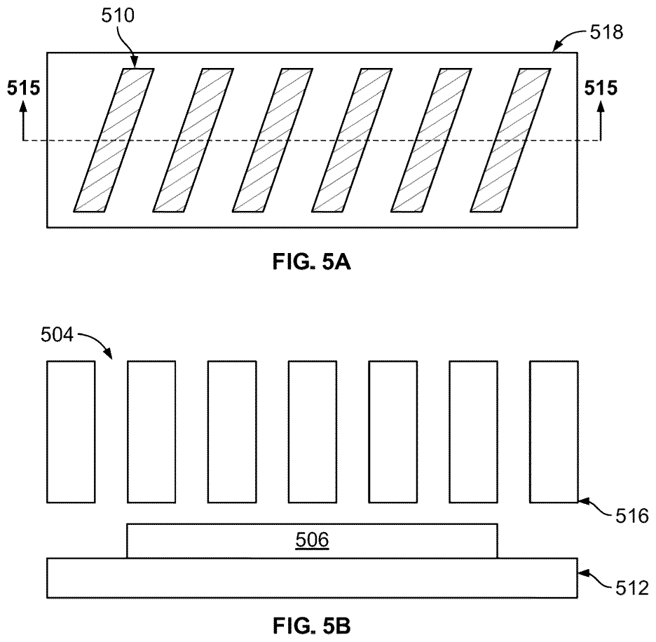

FIG. 5A depicts a top view of an anti-stiction patterned portion of a proof mass comprised of diagonal slit elements in accordance with an embodiment of the present disclosure. This MEMS device 500 is similar to and functions in a similar manner as that of the MEMS device 400. The anti-stiction pattern 518 is comprised of diagonal slit elements 510. FIG. 5B depicts a side view of the MEMS device 500 along a section line 514. The anti-stiction pattern 518 may be applied along an extent that is greater than the width of the bump stop 506 to account for any irregularities and non-idealities in the fabrication process of the MEMS device 500.

The numbered elements of FIGS. 5A-5B are similar to and function in a similar manner as the components of FIG. 4A-4C. However, the anti-stiction pattern 518 is comprised of diagonal slit elements 510. The diagonal slit elements 510 are etched into the first surface 516 of the proof mass 502, which ensures that in the event of a collision, no continuous linear dimension of the bump stop 506 may come in contact with the first surface 516 of the proof mass 502. While a diagonal pattern is shown in this embodiment, others may utilize patterns of varying degrees of offset, spacing, and linearity to achieve a particular performance of the MEMS device 500. Some embodiments may even employ anti-stiction patterns 518 with varying designs of elements across an individual bump stop 506 or between bump stops 506 within the MEMS device 500.

A diagonal slit element 510 is utilized within the anti-stiction pattern 518 that is etched on the first surface 516 and fully through the proof mass 502, such that the top and bottom surface of the proof mass 502 display the pattern. The geometrical dimensions, location, design, curvature, proximity to functional components, amount of removed volume, and pattern density of the diagonal 1 slit elements 510 may be configured during the fabrication process (will be discussed later on). In cases where an extreme external force is applied to the MEMS device 500, the proof mass 502 may collide with the bump stops 506 generating stiction forces. Through the use of the diagonal slit elements 510, the amount of contact area between the first surface 516 of the proof mass 502 and the bump stop 506 may be reduced, thus diminishing the strength of the generated stiction forces.

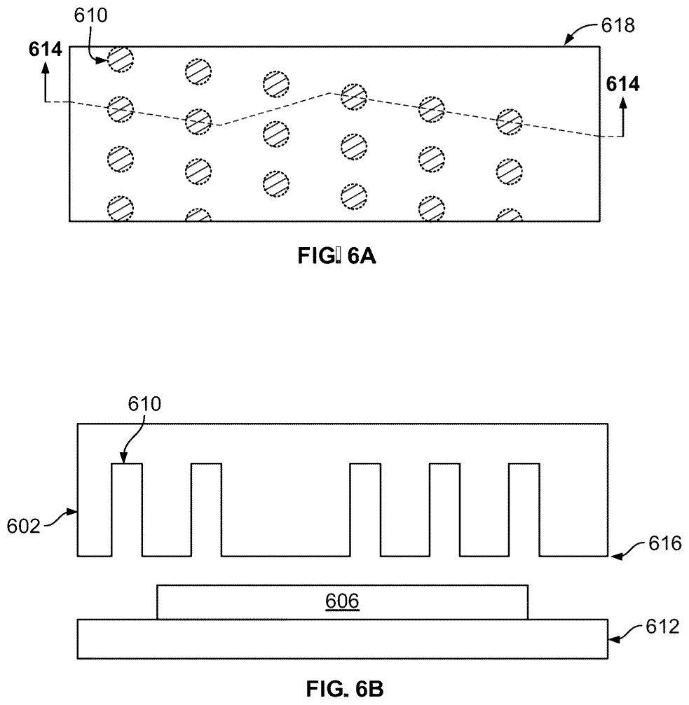

FIG. 6A depicts a top view of an anti-stiction patterned portion of a proof mass comprised of partial through-hole elements in accordance with an embodiment of the present disclosure. This MEMS device 600 is similar to and functions in a similar manner as that of the MEMS device 400. The anti-stiction pattern 618 is comprised of partial through-hole elements 610. FIG. 6B depicts a side view of the MEMS device 600 along a section line 614. The width of the anti-stiction pattern 618 may be applied along an extent that is greater than the width of the bump stop 606 to account for any irregularities and non-idealities in the fabrication process of the MEMS device 600.

The numbered elements of FIGS. 6A and 6B are similar to and function in a similar manner as the components of FIG. 4A-4C. However, the anti-stiction pattern 618 is comprised of partial through-hole elements 610, which do not fully extend through a thickness of the proof mass 602. The partial through-hole elements 610 are etched diagonally into the first surface 616 of the proof mass 602, which ensures that in the event of a collision, no continuous linear dimension of the bump stop 606 may come in contact with the first surface 616 of the proof mass 602. Some embodiments may utilize diagonal patterns and others may utilize patterns of varying degrees of offset, spacing, and linearity to achieve a particular performance of the MEMS device 600. While the embodiment in FIG. 6B shows a uniform depth of the partial through-hole elements 610 within a particular anti-stiction pattern 618 across a single bump stop 606, other embodiments may vary the depth within the same anti-stiction pattered portion 618 or between anti-stiction patterned portions 618 on the proof mass 602. Some embodiments may even employ anti-stiction patterns 618 with varying designs of elements (e.g., through-hole elements, partial through-holes, rectangular slits) across an individual bump stop 606 or between bump stops 606 within the MEMS device 600.

A partial through-hole element 610 is utilized within the anti-stiction pattern 618 that is etched on the first surface 616, but only partially through the proof mass 602, such that the bottom surface of the proof mass 602 displays the pattern, but the top surface of the proof mass 602 does not. The size/diameter, location, shape, design, curvature, linearity, proximity to functional components, amount of removed volume, depth of etching, and pattern density of the partial though-hole elements 610 may be configured during the fabrication process (will be discussed further below). In cases where an extreme external force is applied to the MEMS device 600, the proof mass 602 may collide with the bump stops 606 generating stiction forces. Through the use of the partial through-hole elements 610, the amount of contact area between the first surface 616 of the proof mass 602 and the bump stop 606 may be reduced, thus diminishing the strength of the generated stiction forces. Further, by using partial through-hole elements 610 instead of complete though-hole elements, less volume of proof mass 602 is removed, which may allow for enhanced structural stability and/or functionality of the proof mass 602 during operation of the MEMS device 600.

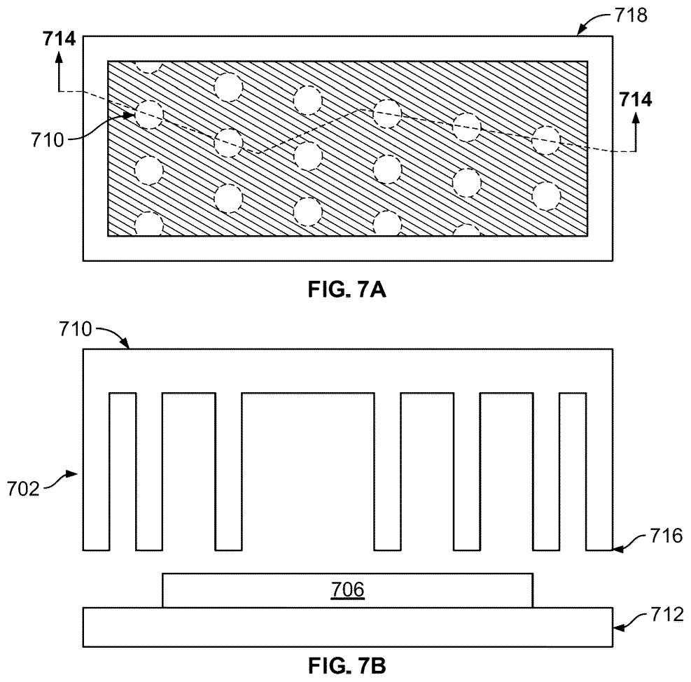

FIG. 7A depicts a top view of an anti-stiction patterned portion of a proof mass comprised of pillar elements in accordance with an embodiment of the present disclosure. This MEMS device 700 is similar to and functions in a similar manner as that of the MEMS device 400 of FIGS. 4A-4C. The anti-stiction pattern 718 is comprised of pillar elements 710. FIG. 7B depicts a side view of the MEMS device 700 along a section line 714. The anti-stiction pattern 718 may be applied along an extent that is greater than the width of the bump stop 706 to account for any irregularities and non-idealities in the fabrication process of the MEMS device 700. The numbered elements of FIGS. 7A and 7B are similar to and function in a similar manner as the components of FIG. 4A-4C. However, the anti-stiction pattern 718 is comprised of pillar elements 710 that extend as circular pillars from within the MEMS layer rather than holes in the MEMS layer. The pillar elements 710 are created by partial etching the first surface 716 of the proof mass 702 around particular regions. Note that the etching does not extend through the entirety of the proof mass 702. Some embodiments may utilize diagonal patterns and others may utilize patterns of varying degrees of offset, spacing, and linearity to achieve a particular performance of the MEMS device 700. The pillars may have a circular, rectangular, square, ovular, or any other shape cross-section. While the embodiment in FIG. 7B shows a uniform depth of etching around the pillar elements 710 within a particular anti-stiction pattern 718 across a single bump stop 706, other embodiments may vary the depth within the same anti-stiction pattered portion 718 or between anti-stiction patterned portions 718 on the proof mass 702. Some embodiments may even employ anti-stiction patterns 718 with varying designs of elements (e.g., with some pillars having oval cross-sections and other pillars having rectangular cross-sections) across an individual bump stop 706 or between bump stops 706 within the MEMS device 700.

A pillar element 710 is utilized within the anti-stiction pattern 718 that is etched on the first surface 716, but only partially through the proof mass 702, such that the bottom or first surface 716 of the proof mass 702 displays the pattern, but the top surface of the proof mass 702 does not. The size/diameter, location, shape, design, curvature, linearity, proximity to functional components, amount of removed volume, depth of etching, and pattern density of the pillar elements 710, and the regions around the pillar elements 710, may be configured during the fabrication process (as will be discussed further below). In cases where an extreme external force is applied to the MEMS device 700, the proof mass 702 may collide with the bump stops 706 generating stiction forces. Through the use of the pillar elements 710, the amount of contact area between the first surface 716 of the proof mass 702 and the bump stop 706 may be reduced, thus diminishing the strength of the generated stiction forces.

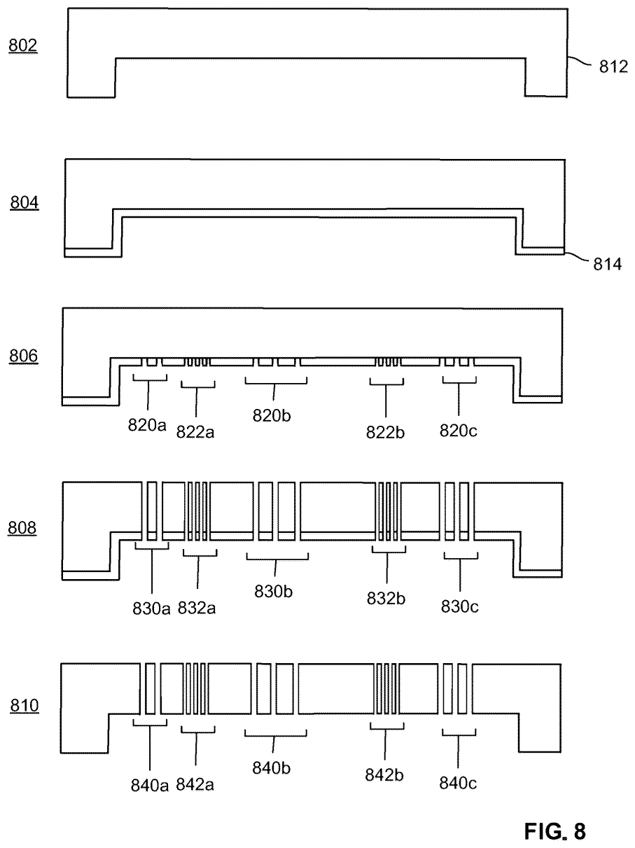

FIG. 8 depicts a side view of a MEMS layer during the fabrication process for through-hole anti-stiction patterning of a MEMS layer in accordance with an embodiment of the present disclosure. The process starts at fabrication step 802 where a MEMS layer 812 is presented (e.g., after initial fabrication steps prior to patterning of features). A mask 814 is deposited over the planar side of the MEMS layer 812 at fabrication step 804. At fabrication step 806, a first set of openings 820 and a second set of openings 822 are created though the mask 814. The MEMS layer 812 exposed by opening the mask in particular areas is etched at fabrication step 808 to create two distinct types of features: functional features 830 (e.g., sense springs, lever arms, masses, etc.) and anti-stiction patterns 832. In fabrication step 810, the mask 814 is completely removed and the completed functional features 840 and anti-stiction patterns 842 of the MEMS layer 812 remain. Note that in this fabrication process, etching for the functional features 830 and anti-stiction pattern 832 occur within a same single fabrication step 808. Although particular fabrication steps are depicted in a certain order, fabrication steps may be removed, modified, and substituted. Further, additional fabrication steps (and the order of those fabrication steps) may be added in certain embodiments.

During the first fabrication step 802 of the fabrication process for anti-stiction patterning of a MEMS layer, the starting MEMS layer 812 is constructed. The MEMS layer 812 may be comprised of silicon, ceramic, polymer composites, glass, or any other combination of materials that is compatible with the fabrication process. The size, properties (e.g., electrical, physical), shape, thickness, design, and configuration may vary between MEMS layers 812. Various coatings and additives may be added to the MEMS layer 812 to alter the effects that each fabrication step may have on it or the overall functionality in the final MEMS device. If necessary, fabrication steps may be added, removed, altered, rearranged, or substituted at any point in the fabrication process in order to achieve a particular MEMS layer 812 configuration. The final MEMS layer 812 post fabrication process may be utilized for any number of purposes with a MEMS device (e.g., functioning as a proof mass).

A mask 814 is deposited over the MEMS layer 812 at the next fabrication step 804, as noted above. The mask 814 may be made from any number of suitable materials, including but not limited to quartz, chrome, resist (e.g., photoresist), composite, or glass. It may be deposited in any amount over any portion of the MEMS layer 812, but generally is deposited over a planar side of the MEMS layer 812. The thickness of the mask 814 may vary between fabrication of different MEMS layers 812 or even across a single MEMS layer 812. One or multiple deposition processes may be utilized to deposit the mask 814.

At fabrication step 806, openings in the mask 814 are created. These openings may be along any portion of the mask 814, but generally are completely through the mask to the MEMS layer 812 below. The size, shape, design, pattern, spacing, location, and number of openings may vary across embodiments depending on the configuration of the fabrication process and the design of the final MEMS device. The openings may be created using a single technique or a combination of techniques, such as photolithography or solvent-based methods. The openings may include a first set of openings 820 and a second set of openings 822. The proximity of the first set of openings 820 to the second set of openings 822 may be variable. The first set of openings 820 may be used as access for creating functional features (e.g., sense springs, lever arms, masses) within the MEMS layer 812, while the second set of openings 822 may be used as access for creating anti-stiction patterns on the MEMS layer 812. The number of holes for the first set of openings 820 and the number of holes for the second set of openings 822 may be one or more than one, and may vary across embodiments.

Etching within the MEMS layer 812 is performed at fabrication step 808. Particular portions of the MEMS layer 812 may be etched due to the selective removal of the mask 814. The regions of the MEMS layer 812 where the mask 814 remains are not impacted or altered during the etching process. The etching process may involve wet etching and/or dry etching techniques. All openings, including the first set of openings 820 and the second set of openings 822, may be selectively etched. The parameters of the etching process may be configured to control and monitor a rate, amount, depth, angle, and permeation of etching within the MEMS layer 812. The embodiment may include partial (i.e., not completely through the MEMS layer 812, to form features such as partial through-holes) and/or complete etching (i.e., through one side and out another side of the MEMS layer 812, to form feature such as through-holes extending entirely through a thickness of the MEMS layer 812). After completion of the etching process, functional features 830 and anti-stiction patterns 832 may be present on and/or within the MEMS layer 812. The parameters of the etching process directly impact the design and characteristics of the formed functional features 830 and anti-stiction patterns 832. Note that in the illustrated example shown in FIG. 8, the density of the anti-stiction patterns 832 tend be greater than the density of the functional features 830.

At fabrication step 810, the mask 814 is removed from the surface of the MEMS layer 812. The mask 814 may be removed using a variety of methods, or combination thereof, including but not limited to wet stripping, dry stripping, or thermal stripping. Once the mask is fully removed, the final version of the MEMS layer 812 remains, which contains the finished functional features 840 and anti-stiction patterns 842.

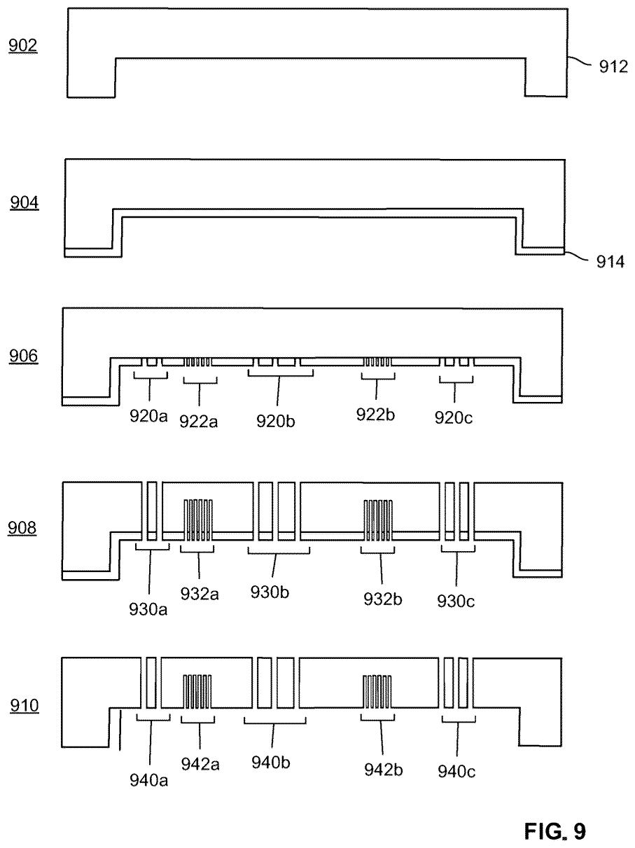

FIG. 9 depicts a side view of a MEMS layer during the fabrication process for partial through-hole anti-stiction patterning of a MEMS layer in accordance with an embodiment of the present disclosure. This fabrication process is similar to and functions in a similar manner as that of the fabrication process depicted in FIG. 8. Instead of utilizing through-hole elements, partial though-hole elements are created during fabrication step 908 within the anti-stiction pattern 932. The numbered elements of FIG. 9 are similar to and function in a similar manner as the components of FIG. 8. However, the second set of openings 922 created at fabrication step 906 have a different design (e.g., greater number of smaller diameter openings). Further, the depth of the etching within the MEMS layer 912 is controlled (e.g., based on etch pattern density of the anti-stiction pattern compared to functional features such as springs) during fabrication step 908 to ensure that a partial through-hole anti-stiction pattern 932 is generated.

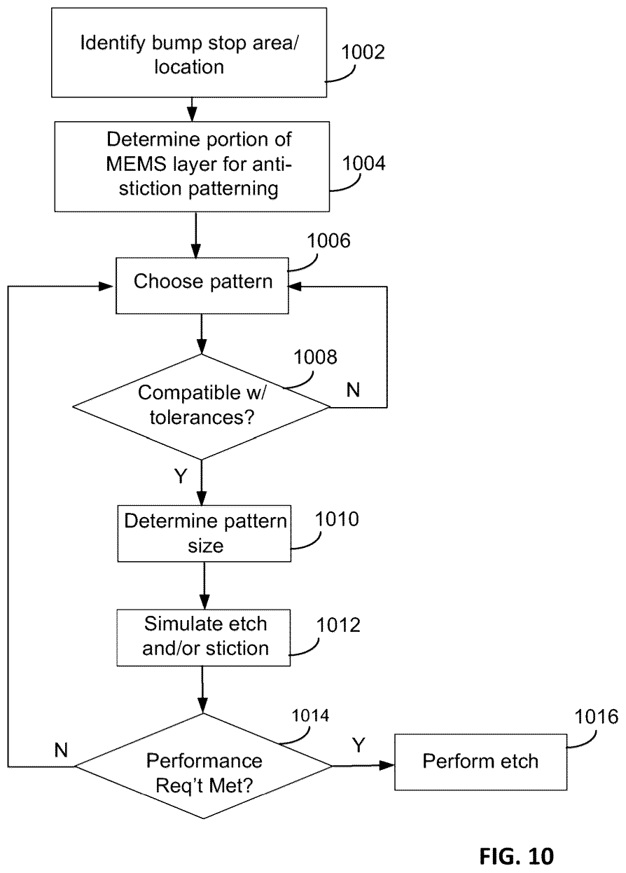

FIG. 10 depicts a flow diagram for a method of anti-stiction patterning of a MEMS layer according to one aspect of an embodiment within the present disclosure. The steps include determining where to etch the anti-stiction patterning, the configuration of the pattern (e.g., size, shape), and simulating its performance to determine if it achieves desirable outcomes. Although particular steps are depicted in a certain order, steps may be removed, modified, and substituted. Further, additional steps (and the order of those steps) may be added in certain embodiments.

Processing may start at block 1002, where the location, along with the size and shape, of the bump stops within a MEMS device is determined. Merely by way of example, potential or predicted stiction forces and characteristics of materials used in forming bump stops may be used to determine appropriate size and/or configurations of bump stops.

Proceeding to block 1004, the portion of the MEMS layer that will receive the anti-stiction patterning is chosen. In order to mitigate generated stiction forces between the MEMS layer and the bump stops, areas of the MEMS layer should be selected or determined that will come in contact with the bump stops. Note that more than one portion of the MEMS layer may receive anti-stiction patterning, depending on the number of bump stops present within the MEMS device.

The anti-stiction pattern is chosen at block 1006. Any number of patterns may be selected. For example, the anti-stiction pattern may consist of through-holes, partial through-holes, rectangular slits, or pillars. A single or combination of patterns may be selected for a single portion or multiple portions of the MEMS layer.

At block 1008 the compatibility of the pattern with MEMS layer process tolerances is determined. In a MEMS layer fabrication process, the tolerances have an impact on the entire configuration of not only the MEMS layer, but also the functioning of the entire MEMS device. Further, the anti-stiction patterning must be compatible with the etching of the functional features within the MEMS layer. The pattern may be chosen to fit within applicable tolerances of the fabrication process (e.g., thickness, alignment accuracy, etch depth, surface roughness, feature size). In the event that the pattern is not compatible (e.g., pattern design requires too small of elements to be etched given applicable tolerances), then the process may return to block 1006 where a new pattern may be chosen. For compatible patterns, the process may proceed to block 1010.

The size of the anti-stiction pattern is selected at block 1010. While the dimensions of the bump stops may aid in determining the selected anti-stiction pattern size, other parameters may also be necessary to consider. For example, due to irregularities and non-idealities that are encountered during the fabrication process of MEMS layers and MEMS devices, it may be prudent to include an excess amount of anti-stiction patterning beyond the dimensions of the bump stop. This overhang of anti-stiction patterning would ensure any misalignments that may occur during the fabrication process between the MEMS layer and the bump stops has minimal impact on the effectiveness of the anti-stiction patterning.

At block 1012, a simulation of the etch and/or stiction forces is performed. Simulations may include the use of various computational algorithms, potentially in combination with empirical data. The results of the simulation are analyzed at block 1014. In cases where the simulations generated acceptable results from the specific anti-stiction pattern, then the process may proceed to block 1016 where etching of the MEMS layer is performed. The etching process may involve wet etching and/or dry etching techniques, and be performed at one or multiple locations across the MEMS layer. In the event that the simulation results were not acceptable, then the process may proceed back to block 1006 where a new pattern is selected that may yield more favorable simulation outcomes.

The foregoing description includes exemplary embodiments in accordance with the present disclosure. These examples are provided for purposes of illustration only, and not for purposes of limitation. It will be understood that the present disclosure may be implemented in forms different from those explicitly described and depicted herein and that various modifications, optimizations, and variations may be implemented by a person of ordinary skill in the present art, consistent with the following claims.

What is claimed is:

1. A microelectromechanical system (MEMS) sensor, comprising:
a base substrate layer;
a MEMS layer comprising a proof mass that moves in a direction towards the base substrate layer and that has a first surface that faces the base substrate layer;
a bump stop located on the base substrate layer and below an overlapping portion of the first surface of the proof mass;
wherein a first pattern is created by a removal of a first portion of material from the proof mass that is located within the overlapping portion of the first surface, and resulting in a reduced contacting area between the proof mass and the bump stop in response to an external force causing the proof mass to contact the bump stop;
wherein a second portion of the material within the MEMS layer is removed at additional locations remote from the overlapping portion, and wherein the removal of the second portion of material corresponds to functional components of a suspended spring-mass system;
wherein the first portion of material and the second portion of the material are removed from the MEMS layer during common material removal steps; and
wherein the first pattern extends only partially into the MEMS layer.

2. The MEMS sensor of claim 1, wherein the functional components comprise a plurality of springs that suspend the proof mass within the suspended spring-mass system.

3. The MEMS sensor of claim 1, wherein the common material removal steps comprise common etching steps.

4. The MEMS sensor of claim 2, wherein the common etching steps comprise a single etching step.

5. The MEMS sensor of claim 1, wherein an adhesion force between the bump stop and the overlapping portion of the first surface of the proof mass is reduced based on the first pattern.

6. The MEMS sensor of claim 5, wherein the reduction in the adhesion force is proportional to an area of the first portion of material within the overlapping portion.

7. The MEMS sensor of claim 1, wherein the proof mass absorbs a first contact force when the first patter of the proof mass contacts the bump stop.

8. The MEMS sensor of claim 1, wherein the first pattern comprises a plurality of pillars.

9. The MEMS sensor of claim 1, wherein the first pattern comprises a plurality of circular shapes of removed material or a plurality of strips of removed material.

10. The MEMS sensor of claim 1, wherein the first pattern includes a plurality of offset shapes.

11. The MEMS sensor of claim 10, wherein the plurality of offset shapes are sized and placed such that no linear dimension of the bump stop is in contact with the overlapping portion of the proof mass over an entirety of the linear dimension.

12. A method for fabricating a microelectromechanical system (MEMS) sensor, comprising:
providing a MEMS layer;
patterning the MEMS layer, wherein a first portion of the patterning comprises a first pattern corresponding a first portion of the MEMS layer that overlaps with a bump stop located below the MEMS layer and results in a reduced surface area that comes into contact with the bump stop in response to an external force causing a proof mass to contact the bump stop, and wherein a second portion of the patterning comprises a second pattern corresponding to a second portion of the MEMS layer that is remote from the first portion of the MEMS layer and that corresponds to functional components of a suspended spring-mass system; and
simultaneously partially removing material from the MEMS layer based on the first pattern and completely removing material from the MEMS layer based on the second pattern to fabricate the first pattern that overlaps with the bump stop and the second pattern that corresponds to functional components of the suspended spring-mass system.

13. The method of claim 12, wherein the functional components comprise a plurality of springs that suspend the proof mass within the suspended spring-mass system.

14. The method of claim 12, wherein the first pattern comprises a plurality of pillars.

15. The method of claim 12, wherein the first pattern comprises a plurality of circular shapes of removed material or a plurality of strips of removed material.

16. The method of claim 12, wherein the first patterned portion of material includes a plurality of offset shapes.

17. The method of claim 16, wherein the plurality of offset shapes are sized and placed such that no linear dimension of the bump stop is in contact with an overlapping portion of the proof mass over an entirety of the linear dimension.

18. The method of claim 12, wherein the MEMS sensor comprises an accelerometer or a gyroscope.

19. The method of claim 12, wherein the MEMS sensor comprises a microphone or a pressure sensor, and wherein the proof mass comprises a diaphragm.

20. The method of claim 12, wherein an adhesion force between the bump stop and an overlapping portion of the first surface of the proof mass is reduced based on the first pattern.
